(19) United States
(12) Patent Application Publication
(10) Pub. No.: US 2015/0221882 A1
(43) Pub. Date: Aug. 6, 2015

(54) COMPOUND FOR ORGANIC ELECTROLUMINESCENCE DEVICE AND ORGANIC ELECTROLUMINESCENCE DEVICE INCLUDING THE SAME

(71) Applicant: SAMSUNG DISPLAY CO., LTD., Yongin-City (KR)

(72) Inventors: Masatsugu UENO, Yokohama (JP); Yasuo MIYATA, Yokohama (JP)

(21) Appl. No.: 14/610,224

(22) Filed: Jan. 30, 2015

(30) Foreign Application Priority Data
Feb. 4, 2014 (JP) 2014-019773

(51) Int. Cl. H01L 51/00; H01L 51/50; C07F 7/10

(52) U.S. Cl. CPC H01L 51/0094; C07F 7/10; H01L 51/5088; H01L 51/5056; H01L 51/5012

(57) ABSTRACT

A compound for an organic electroluminescence (EL) device is represented by the following Formula (1):

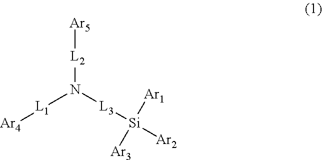

where Ar₁, Ar₂ and Ar₃ are independently a substituted or unsubstituted aryl group, a substituted or unsubstituted heteroaryl group, or a substituted or unsubstituted alkyl group,
at least one of Ar₁, Ar₂ and Ar₃ includes an electron withdrawing group,
Ar₄ and Ar₅ are independently a substituted or unsubstituted aryl group having 6 to 30 ring carbon atoms, a substituted or unsubstituted heteroaryl group having 1 to 30 ring carbon atoms, or a substituted or unsubstituted alkyl group having 1 to 15 carbon atoms, and
L₁, L₂ and L₃ are a single bond or a divalent conjugated connecting group

### CROSS-REFERENCE TO RELATED APPLICATION

Japanese Patent Application No. 2014-019773, filed on Feb. 4, 2014, in the Japanese Patent Office, and entitled: “Material for Organic Electroluminescence Device and Organic Electroluminescence Device Including the Same,” is incorporated by reference herein in its entirety.

### BACKGROUND

1. Field

Embodiments relate to a compound for an organic electroluminescence device and an organic electroluminescence device including the same.

2. Description of the Related Art

In recent years, organic electroluminescence (EL) displays that are one type of image displays have been actively developed. Unlike a liquid crystal display and the like, the organic EL display is so-called a self-luminescent display which recombines holes and electrons injected from an anode and a cathode in an emission layer to thus emit lights from a light-emitting material including an organic compound of the emission layer, thereby performing display.

### SUMMARY

Embodiments are directed to a compound for an organic electroluminescence (EL) device represented by the following Formula (1).

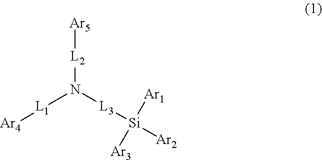

where Ar₁, Ar₂ and Ar₃ are a substituted or unsubstituted aryl group, a substituted or unsubstituted heteroaryl group, or a substituted or unsubstituted alkyl group, and at least one of Ar₁, Ar₂ and Ar₃ includes an electron withdrawing group, Ar₄ and Ar₅ are a substituted or unsubstituted aryl group having 6 to 30 ring carbon atoms, a substituted or unsubstituted heteroaryl group having 1 to 30 ring carbon atoms, or a substituted or unsubstituted alkyl group having 1 to 15 carbon atoms, and L₁, L₂ and L₃ are a single bond or a divalent conjugated connecting group.

L₃ may be an arylene group having 6 to 18 ring carbon atoms.

A hole transport material may include the compound for an organic EL device represented by Formula 1.

The hole transport material may include the compound for an organic EL device represented by Formula 1, where L₃ is an arylene group having 6 to 18 ring carbon atoms.

Embodiments are also directed to an organic EL device including the compound for an organic EL device represented by Formula 1 in an emission layer. The compound may be in a layer of stacked layers between an emission layer and an anode.

Embodiments are also directed to an organic EL device including the compound for an organic EL device represented by Formula 1 in an emission layer, where L₃ is an arylene group having 6 to 18 ring carbon atoms. The compound may be in a layer of stacked layers between an emission layer and an anode.

Embodiments are also directed to an organic electroluminescence (EL) device including an anode, a hole injection layer, a hole transport layer, an emission layer, an electron transport layer, an electron injection layer, and a cathode stacked in order. One layer of the hole injection layer, the hole transport layer and the emission layer includes a compound for an organic EL device represented by the following Formula (1):

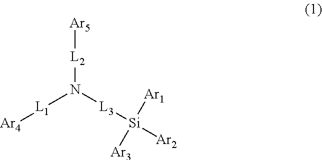

where Ar₁, Ar₂ and Ar₃ are independently a substituted or unsubstituted aryl group, a substituted or unsubstituted heteroaryl group, or a substituted or unsubstituted alkyl group, at least one of Ar₁, Ar₂ and Ar₃ includes an electron withdrawing group, Ar₄ and Ar₅ are independently a substituted or unsubstituted aryl group having 6 to 30 ring carbon, a substituted or unsubstituted heteroaryl group having 1 to 30 ring carbon, or a substituted or unsubstituted alkyl group having 1 to 15 carbon atoms, and L₁, L₂ and L₃ are a single bond or a divalent conjugated connecting group.

### BRIEF DESCRIPTION OF THE DRAWING

Features will become apparent to those of skill in the art by describing in detail exemplary embodiments with reference to the attached drawing in which:

FIG. 1 illustrates a schematic diagram of an organic EL device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Like reference numerals refer to like elements throughout.

In a common amine derivative containing a phenylsilyl group, a HOMO level may be low, and sufficient emission efficiency may not be attained. In an embodiment, an electron withdrawing group may be introduced into a phenylsilyl group to increase the HOMO level. Thus, the emission efficiency of an organic EL device may be improved.

Hereinafter, the material or compound for an organic EL device and an organic EL device using the same according to embodiments will be explained referring to attached drawings.

A material or compound for an organic EL device according to embodiments may be an amine derivative containing a silyl group as represented in the following Formula (1).

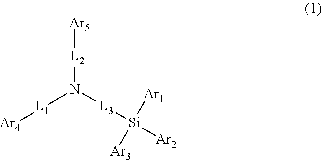

In Formula (1), Ar₁, Ar₂ and Ar₃ may be a substituted or unsubstituted aryl group, a substituted or unsubstituted heteroaryl group, or a substituted or unsubstituted alkyl group. At least one of Ar₁, Ar₂ and Ar₃ may include an electron withdrawing group.

Ar₄ and Ar₅ may be a substituted or unsubstituted aryl group having 6 to 30 ring carbon atoms, a substituted or unsubstituted heteroaryl group having 1 to 30 ring carbon atoms, or a substituted or unsubstituted alkyl group having 1 to 15 carbon atoms. L₁, L₂ and L₃ may be a single bond or a divalent conjugated connecting group.

Particular examples of the aryl group in the “substituted or unsubstituted aryl group” and the heteroaryl group in the “substituted or unsubstituted heteroaryl group” of Ar₁, Ar₂ and Ar₃ may include a phenyl group, a naphthyl group, an anthracenyl group, a phenanthryl group, a biphenyl group, a terphenyl group, a fluorenyl group, a triphenylene group, a biphenylene group, a pyrenyl group, a benzothiazolyl group, a thiophenyl group, a thienothiophenyl group, a thienothienothiophenyl group, a benzothiophenyl group, a dibenzothiophenyl group, a dibenzofuryl group, an N-arylcarbazolyl group, an N-heteroarylcarbazolyl group, an N-alkylcarbazolyl group, a phenoxazyl group, a phenothiazinyl group, a pyridyl group, a pyrimidyl group, a triazyl group, a quinolyl group, a quinoxalyl group, without limitation. For example, the aryl group or the heteroaryl group of Ar¹, Ar² and Ar³ may include a phenyl group, a naphthyl group, a biphenyl group, a terphenyl group, a fluorenyl group, a triphenylene group, a dibenzothiophenyl group, a dibenzofuryl group or a N-phenylcarbazolyl group. For example, the aryl group or the heteroaryl group of Ar¹, Ar² and Ar³ may be a phenyl group, a biphenyl group, a fluorenyl group, a triphenylene group, a dibenzothiophenyl group, a dibenzofuryl group or a N-phenylcarbazolyl group.

Examples of the alkyl group in the “substituted or unsubstituted alkyl group” of Ar₁, Ar₂ and Ar₃ may include a methyl group, an ethyl group, a propyl group, an isopropyl group, a cyclopropyl group, a butyl group, an isobutyl group, a t-butyl group, a cyclobutyl group, a pentyl group, an isopentyl group, a neopentyl group, a cyclopentyl group, a hexyl group, a cyclohexyl group, a heptyl group, a cycloheptyl group, an octyl group, a nonyl group, a decyl group, etc.

Examples of the substituent of the aryl group, the heteroaryl group or the alkyl group of Ar₁, Ar₂ and Ar₃ may include an alkyl group, an alkoxy group, an aryl group or a heteroaryl group.

Examples of the alkyl group of the substituent of the aryl group, the heteroaryl group or the alkyl group of Ar₁, Ar₂ and Ar₃ may include a methyl group, an ethyl group, a propyl group, an isopropyl group, a cyclopropyl group, a butyl group, an isobutyl group, a t-butyl group, a cyclobutyl group, a pentyl group, an isopentyl group, a neopentyl group, a cyclopentyl group, a hexyl group, a cyclohexyl group, a heptyl group, a cycloheptyl group, an octyl group, a nonyl group, a decyl group, etc.

Examples of the alkoxy group of the substituent of the aryl group or the heteroaryl group of Ar₁, Ar₂ and Ar₃ may include a methoxy group, an ethoxy group, an n-propoxy group, an isopropoxy group, an n-butoxy group, an isobutoxy group, a t-butoxy group, an n-pentyloxy group, a neopentyloxy group, an n-hexyloxy group, an n-heptyloxy group, an n-octyloxy group, a 2-ethylhexyloxy group, a nonyloxy group, a decyloxy group, a 3,7-dimethyloctyloxy group, etc.

Examples of the aryl group and the heteroaryl group of the substituent of the aryl group or the heteroaryl group of Ar₁, Ar₂ and Ar₃ may include a phenyl group, a naphthyl group, an anthracenyl group, a phenanthryl group, a biphenyl group, a terphenyl group, a fluorenyl group, a triphenylene group, a biphenylene group, a pyrenyl group, a benzothiazolyl group, a thiophenyl group, a thienothiophenyl group, a thienothienothiophenyl group, a benzothiophenyl group, a dibenzothiophenyl group, a dibenzofuryl group, an N-arylcarbazolyl group, an N-heteroarylcarbazolyl group, an N-alkylcarbazolyl group, a phenoxazyl group, a phenothiazyl group, a pyridyl group, a pyrimidyl group, a triazyl group, a quinolyl group or a quinoxalyl group. The aryl group and the heteroaryl group of the substituent of the aryl group or the heteroaryl group of Ar¹, Ar² and Ar³ may be a phenyl group, a naphthyl group, a biphenyl group, a terphenyl group, a fluorenyl group, a triphenylene group, a dibenzothiophenyl group, a dibenzofuryl group or a N-phenylcarbazolyl group. For example, the aryl group and the heteroaryl group of the substituent of the aryl group or the heteroaryl group of Ar¹, Ar² and Ar³ may be a phenyl group, a biphenyl group, a fluorenyl group, a triphenylene group, a dibenzothiophenyl group, a dibenzofuryl group or a N-phenylcarbazolyl group.

In the above Formula (1), the electron withdrawing group included in Ar₁, Ar₂ and Ar₃ may be selected from, for example, a nitro group, a cyano group, an acyl group or a halogen atom. In some implementations, two of Ar₁, Ar₂ and Ar₃ may include the electron withdrawing groups, or all of Ar₁, Ar₂ and Ar₃ may include the electron withdrawing groups. The material or compound for an organic EL device according to embodiments may be an amine derivative containing a silyl group including at least one electron withdrawing group. Through increasing the HOMO level, the emission efficiency of the organic EL device may be improved.

In an amine derivative containing a silyl group, an electron withdrawing group could be introduced in other than the silyl group. However, according to embodiments, the electron withdrawing group is introduced in the silyl group to restrain the influence to a conjugated system. In addition, the silyl group may have strong electron tolerance. Accordingly the long life of the organic EL device may be maintained.

In an embodiment, the aryl group of Ar₄ and Ar₅ may be a substituted or unsubstituted aryl group having 6 to 30 ring carbon atoms among the aryl groups among the above-described “substituted or unsubstituted aryl group.”

In an embodiment, the heteroaryl group of Ar₄ and Ar₅ may be a substituted or unsubstituted heteroaryl group having 1 to 30 ring carbon atoms among the heteroaryl groups of the above-described “substituted or unsubstituted heteroaryl group.”

In an embodiment, the alkyl group of Ar₄ and Ar₅ may be a substituted or unsubstituted alkyl group having 1 to 15 carbon atoms among the alkyl groups of the above-described “substituted or unsubstituted alkyl group.”

In an embodiment, the divalent conjugated connecting group used as L₁, L₂ and L₃ may include an arylene group having 6 to 30 ring carbon atoms The arylene group may be selected from, for example, the same groups as the aryl group of the above described “substituted or unsubstituted aryl group.”. In an embodiment, L₃ may be an arylene group having 6 to 18 ring carbon For example, L₃ may be a phenylene group, a biphenylene group or a terphenylene group. If the ring carbon number were to exceed 18, a gap could be undesirably decreased.

The compound for an organic EL device according to embodiments may be, for example, a compound illustrated in the following structures 1 to 6.

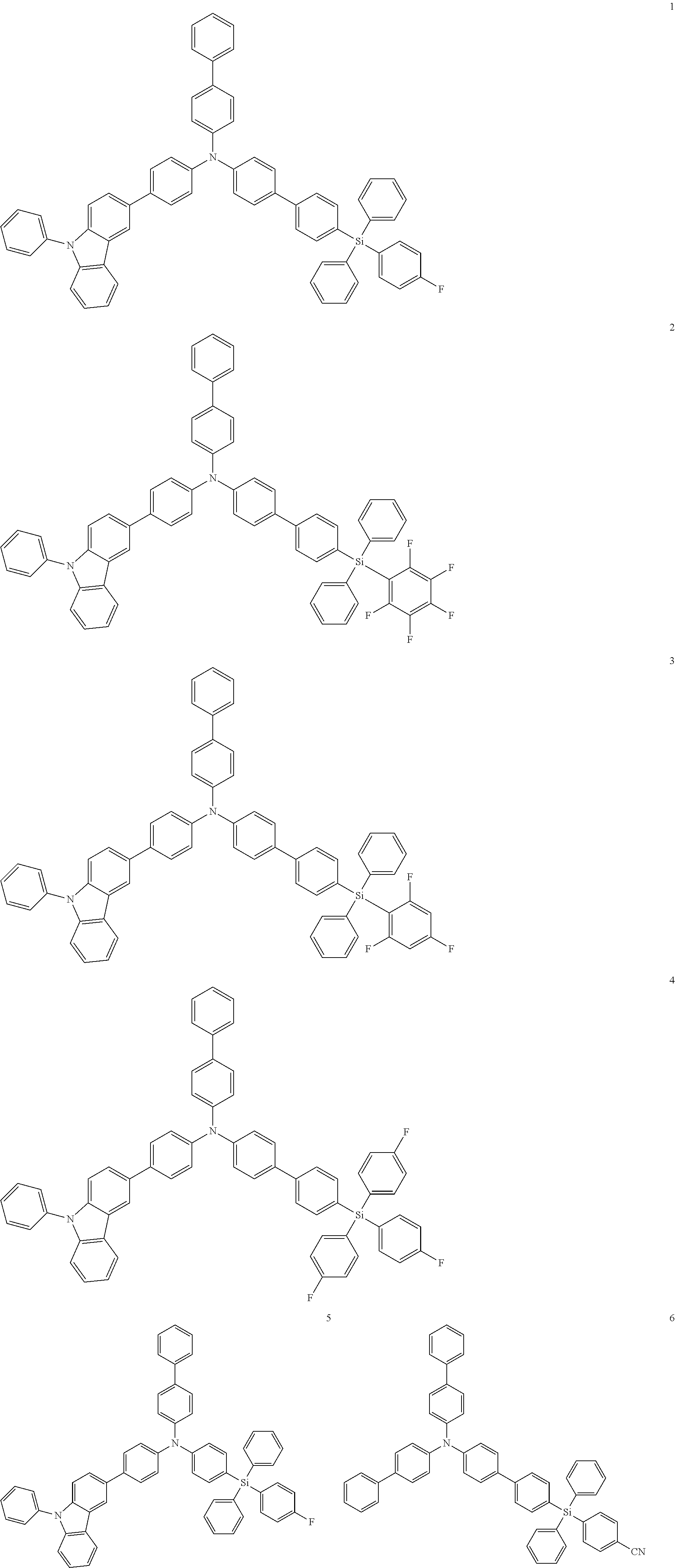

The compound for an organic EL device according to embodiments may be, for example, a compound illustrated in the following structures 7 to 12.

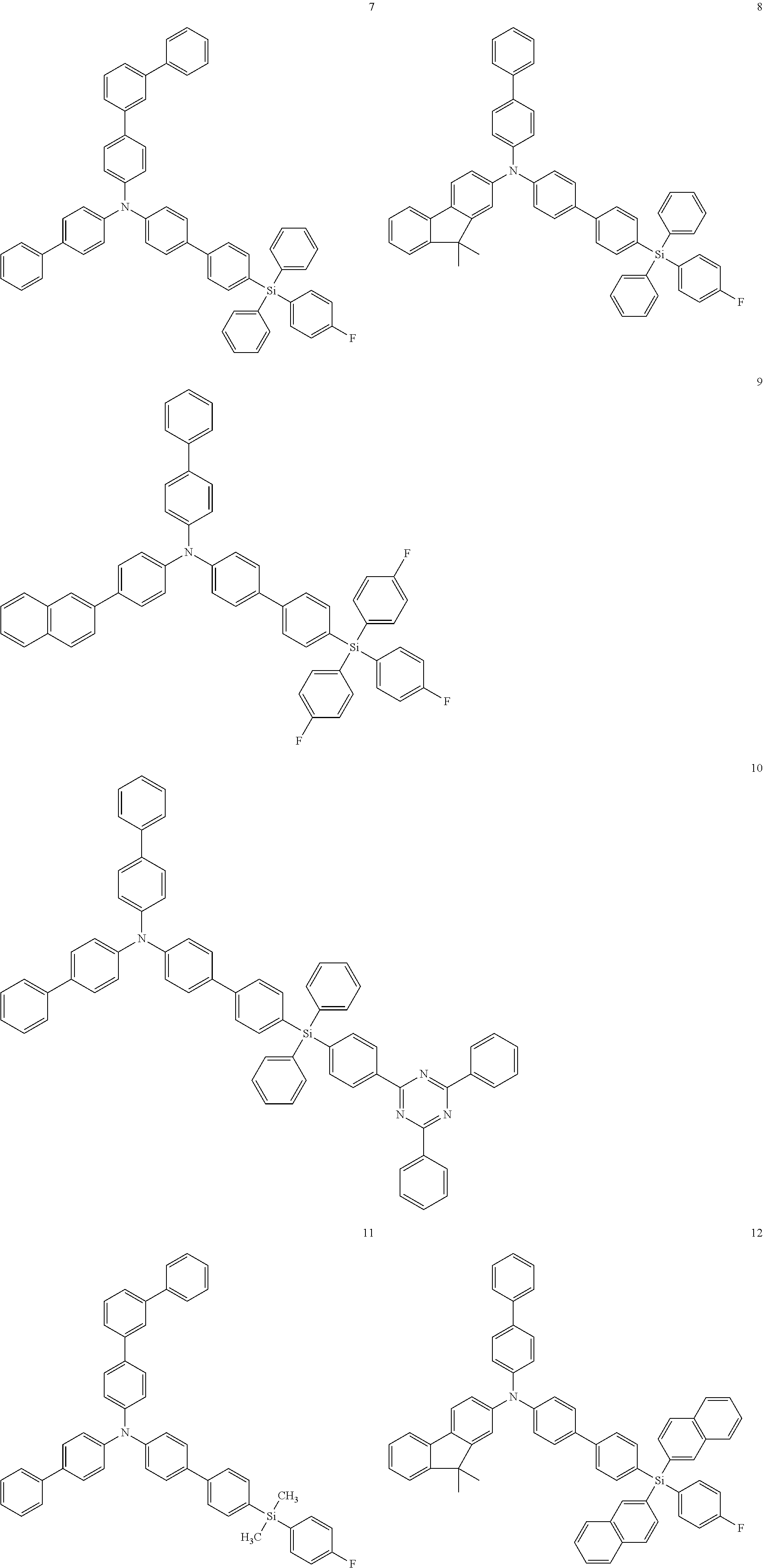

The compound for an organic EL device according to embodiments may be an amine derivative containing a silyl group. The amine derivative containing the silyl group may include at least one electron withdrawing group in the silyl group. Thus, HOMO level may be increased, and thus, the emission efficiency of the organic EL device may be improved. The material for an organic EL device according to the embodiments may be appropriately used in the emission layer of the organic EL device. In addition, the compound for an organic EL device according embodiments may be used in a layer of stacked layers between the emission layer and the anode. Therefore, hole transport properties may be improved, and the high emission efficiency of the organic EL device may be realized.

(Organic EL Device)

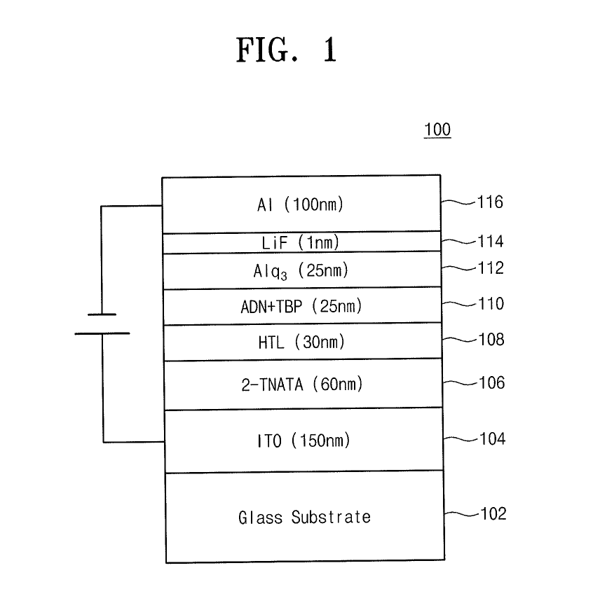

An organic EL device using the compound for an organic EL device according to the embodiments will be explained. FIG. 1 illustrates a schematic diagram illustrating an organic EL device 100 according to an embodiment. (In addition, FIG. 1 illustrates the specific materials and layer thicknesses used in the Examples and Comparative Examples discussed below.) The organic EL device 100 may include, for example, a substrate 102, an anode 104, a hole injection layer 106, a hole transport layer 108, an emission layer 110, an electron transport layer 112, an electron injection layer 114 and a cathode 116. In an embodiment, the material for an organic EL device according to an embodiment may be used in an emission layer of an organic EL device. In another embodiment, the material for an organic EL device may be used in a layer of stacked layers disposed between an emission layer and an anode.

For example, an embodiment using the material for an organic EL device according to embodiments in the hole transport layer 108 will be explained. The substrate 102 may be a transparent glass substrate, a semiconductor substrate completed by using silicon, a resin, etc. In some implementations, the substrate 102 may be a flexible substrate. The anode 104 may be disposed on the substrate 102. The anode 104 may be formed using indium tin oxide (ITO), indium zinc oxide (IZO), etc. The hole injection layer 106 may be disposed on the anode 104. The hole injection layer 106 may include, for example, 4,4′,4″-tris[2-naphthyl(phenyl)amino]triphenylamine (2-TNATA), N,N,N′,N′-tetrakis(3-methylphenyl)-3,3′-dimethylbenzidine (HMTPD), etc. The hole transport layer 108 may be disposed on the hole injection layer 106. The hole transport layer 108 may be formed using the material for an organic EL device according to an embodiment. The emission layer 110 may be disposed on the hole transport layer 108. The emission layer 110 may be formed using the material for an organic EL device according to an embodiment. In some implementations, the emission layer 110 may be formed, for example, by doping a host material including 9,10-di(2-naphthyl)anthracene (ADN) with 2,5,8,11-tetra-t-butylperylene (TBP). The electron transport layer 112 may be disposed on the emission layer 110 and may be formed using, for example, tris(8-hydroxyquinolinato)aluminum (Alq3).

The electron injection layer 114 may be disposed on the electron transport layer 112. The electron injection layer 114 may be formed using, for example, a material including lithium fluoride (LiF). The cathode 116 may be disposed on the electron injection layer 114. The cathode may be formed using a metal such as aluminum or a transparent material such as ITO or IZO. The thin layers may be formed by an appropriate layer forming method such as a vacuum deposition method, a sputtering method, various coating methods, etc. according to the materials.

In the organic EL device 100 according to an embodiment, the compound for an organic EL device may be used, and a hole transport layer realizing high efficiency may be formed. The compound for an organic EL device may be applied in an organic EL apparatus of an active matrix type that uses thin film transistors (TFT).

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

(Preparation Methods)

The above-described materials for an organic EL device according to embodiments may be synthesized, for example, by the following methods.

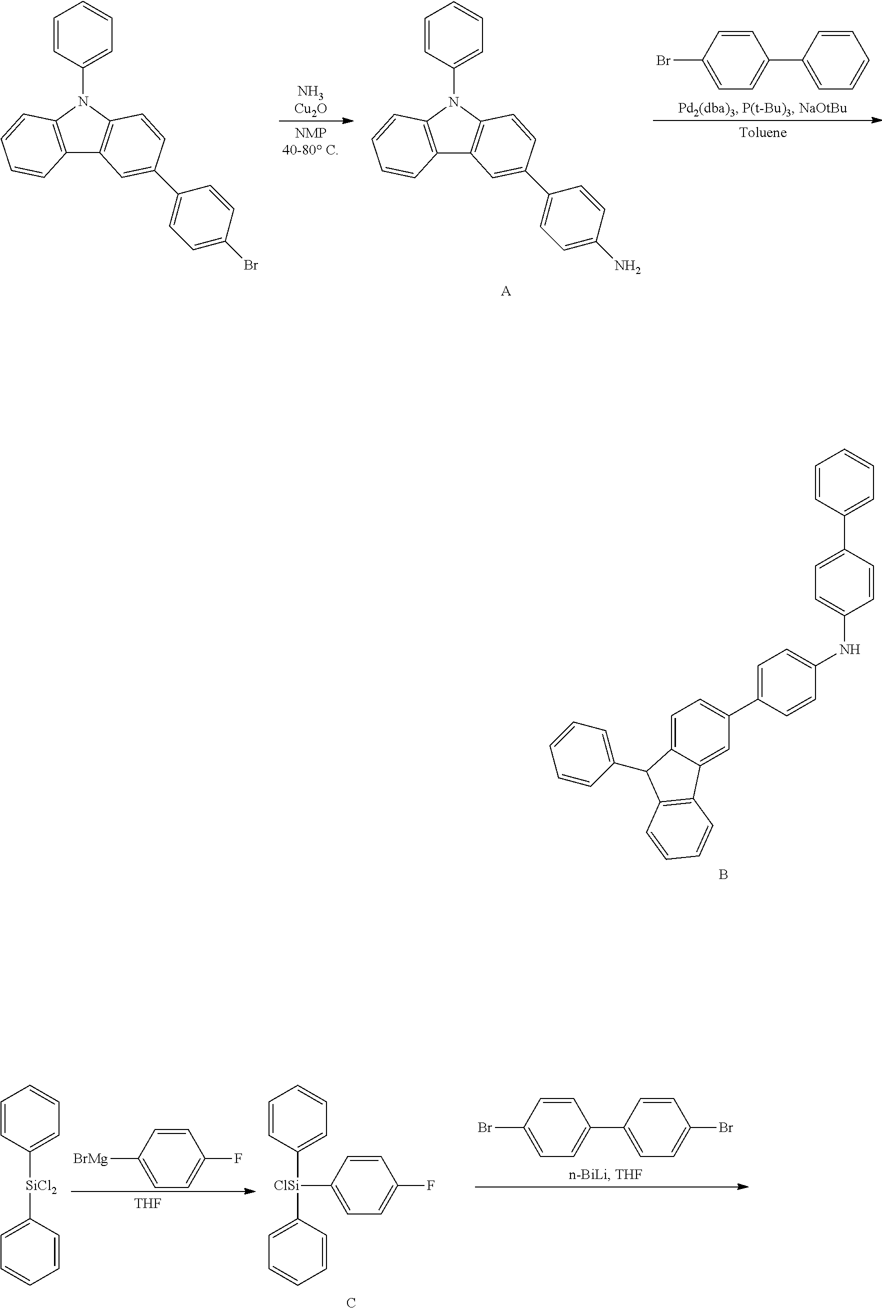

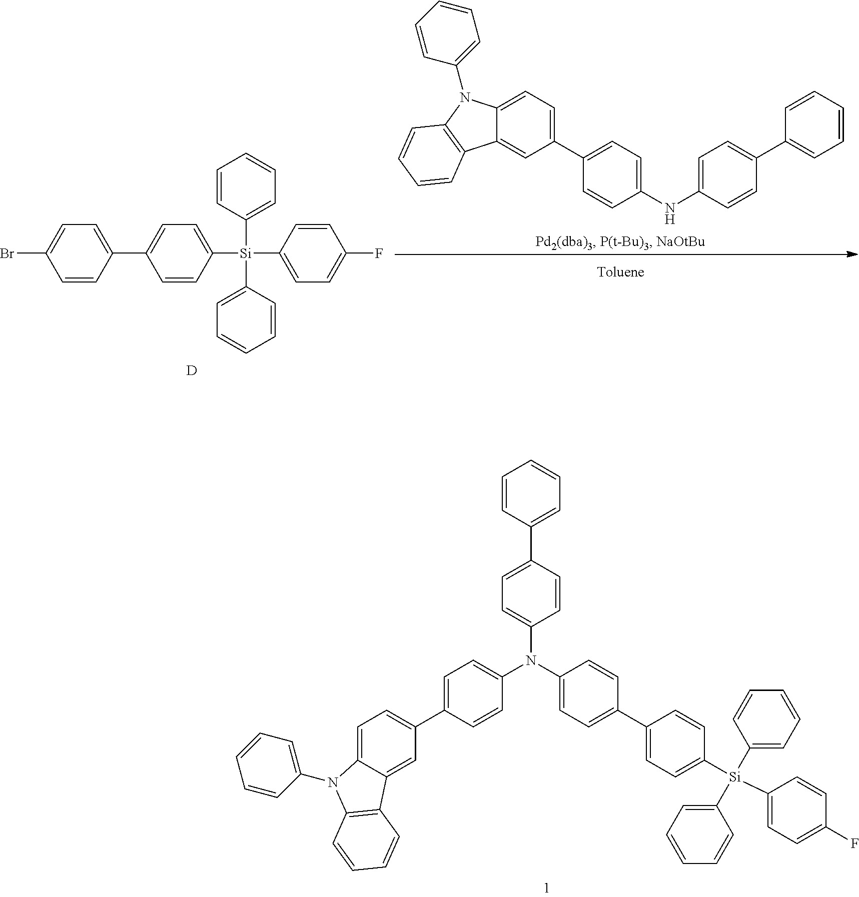

(Synthesis of Compound A)

Under an argon gas atmosphere, 2.0 g of 3-(4-bromophenyl)-9-phenyl-9H-carbazole, 0.072 g of copper(I) oxide, 10.2 mL of N-methyl pyrrolidone and 3.4 mL of 28% aqueous ammonia were added in a 300 mL Schlenk flask, followed by heating and stirring at 40 degrees (hereinafter, degrees Celsius) for 10 minutes. After elevating the temperature to 80 degrees, the heating and stirring were performed for 12 hours. Water was poured into the reactant and extraction with ethyl acetate was performed. The solvents were removed under a reduced pressure, and the crude product thus obtained was separated by silica gel column chromatography to yield 1.6 g of Compound A.

(Synthesis of Compound B)

Under an argon atmosphere, 1.5 g of Compound A, 1.50 g of 4-bromobiphenyl, 0.23 g of tris(dibenzylideneacetone) dipalladium(O) (Pd₂(dba)₃), 0.18 g of tri-tert-butylphosphine ((t-Bu)₃P) and 0.86 g of sodium tert-butoxide were added to a 200 mL, three-necked flask, followed by heating while stirring at 80 degrees for 1.5 hours. After cooling in the air, water was poured into the reactant for washing. Solvents in an organic layer were distilled off. The residue thus obtained was separated by silica gel column chromatography to yield 1.86 g of Compound B.

(Synthesis of Compound C)

Under an argon atmosphere, 3.0 g of dichlorodiphenylsilane was added to a 100 mL, four-necked flask and dissolved in 6 mL of tetrahydrofuran (THF). Then, 13.16 mL of 4-fluorophenyl magnesium bromide in an 18% THF solution was added drop by drop, followed by heating while refluxing for 5 hours. THF was distilled off under a reduced pressure, and the residue thus obtained was separated using hexane. The precipitate was separated, and solvents were distilled off under a reduced pressure to yield 1.9 g of Compound C.

(Synthesis of Compound D)

Under an argon atmosphere, 1.5 g of 4,4′-dibromobiphenyl and 9.6 mL of THF were added to a 100 mL, four-necked flask and cooled to −78 degrees. 3 mL of 1.64 M of n-butyllithium (in a n-hexane solution) was added thereto, followed by stirring at −78 degrees for 1 hour. Then, 1.5 g of Compound C was added thereto, followed by stirring at −78 degrees for 1 hour. The temperature was gradually increased to room temperature, followed by stirring at room temperature for 1 hour. The solid thus produced was separated and purified by silica gel column chromatography to produce 1.10 g of Compound D.

(Synthesis of Compound 1)

Under an argon atmosphere, 1.05 g of Compound B, 1.10 g of Compound D, 0.11 g of tris(dibenzylideneacetone) dipalladium(O) (Pd₂(dba)₃), 0.30 mg of tris-tert-butylphosphine ((t-Bu)₃P), and 0.41 g of sodium tert-butoxide in a 100 mL, three-necked flask, followed by heating while stirring in a 22 mL toluene solvent at 80 degrees for 1.5 hours. After cooling in the air, water was poured into the reactant, and an organic layer was separated. Solvents were distilled off, and the residue thus obtained was separated by silica gel column chromatography to yield 1.70 g of Compound 1.

Organic EL devices of Examples 1 to 4 were manufactured using the hole transport materials of the above Compounds 1, 2, 4 and 5 by the above-described method. In addition, organic EL devices of Comparative Examples 1 and 2 were manufactured using the following Compounds 13 and 14 as hole transport materials.

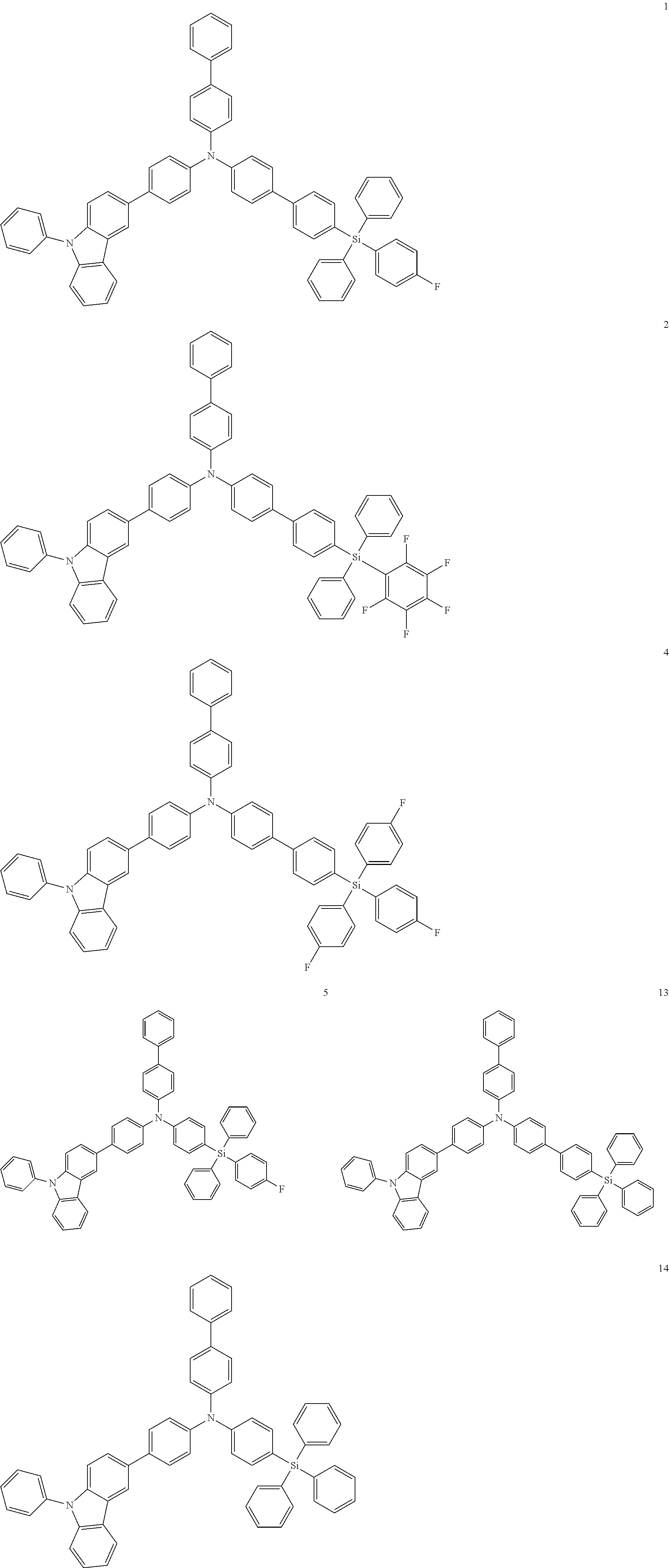

For purposes of the Examples and Comparative Examples, the substrate 102 was formed using a transparent glass substrate, the anode 104 was formed using ITO to a thickness of about 150 nm, the hole injection layer 106 was formed using 2-TNATA to a thickness of about 60 nm, the hole transport layer 108 was formed using the compounds of the examples or the comparative examples to a thickness of about 30 nm, the emission layer 110 was formed using ADN doped with 3% TBP to a thickness of about 25 nm, the electron transport layer 112 was formed using Alq₃ to a thickness of about 25 nm, the electron injection layer 114 was formed using LiF to a thickness of about 1 nm, and the cathode 116 was formed using Al to a thickness of about 100 nm.

With respect to the organic EL devices thus manufactured, the voltage and the emission efficiency were evaluated. The evaluation was conducted at the current density of 10 mA/cm².

TABLE 1

| | | | Emission |
|---|---|---|---|
| Device manufacturing | | Voltage | efficiency |
| Example | Hole transport layer | (V) | (cd/A) |
| Example 1 | Exemplary Compound 1 | 5.7 | 7.8 |
| Example 2 | Exemplary Compound 2 | 6.0 | 7.3 |
| Example 3 | Exemplary Compound 4 | 5.9 | 7.6 |
| Example 4 | Exemplary Compound 5 | 5.8 | 7.7 |
| Comparative | Comparative Compound 13 | 6.7 | 6.9 |
| Example 1 | | | |
| Comparative | Comparative Compound 14 | 6.8 | 6.7 |
| Example 2 | | | |

As may be seen from the results in Table 1, the organic EL devices according to Examples 1 to 4 were driven at a lower voltage and have higher emission efficiency when compared to organic EL devices according to the comparative examples. When comparing Example 1 with Comparative Example 1, or Example 5 with Comparative Example 2, the emission efficiency was significantly improved in Example 1 or 5 through the introduction of a fluorine atom as the electron withdrawing group in the silyl group. In addition, the emission efficiency was also improved even though changing the electron withdrawing group as in Example 2. Further, the emission efficiency was also improved even though increasing the numbers of the electron withdrawing groups as in Example 3.

By way of summation and review, an example of an organic electroluminescence device (organic EL device) known in the art is an organic EL device which includes an anode, a hole transport layer disposed on the anode, an emission layer disposed on the hole transport layer, an electron transport layer disposed on the emission layer, and a cathode disposed on the electron transport layer. Holes injected from the anode are injected into the emission layer via the hole transport layer, and electrons are injected from the cathode, and then injected into the emission layer via the electron transport layer. The holes and the electrons injected into the emission layer recombine to generate excitons within the emission layer. The organic EL device emits light generated during the transition of the excitons to a ground state.

In the application of the organic EL device in a display apparatus, improvement of the emission efficiency of the organic EL device is desirable. Particularly, the emission efficiency of the organic EL device in a blue emission region and a green emission region may be insufficient when compared to that in a red emission region. To realize the high emission efficiency of the organic EL device, the normalization and the stabilization of a hole transport layer have been examined. As hole transport materials used in the hole transport layer, various compounds such as a carbazole derivative, carbazole derivative substituted with a condensed ring, or an aromatic amine compound may be used. An amine derivative containing a phenylsilyl group has been suggested as an organic photosensitive material or a coating type material of the organic EL device. However, the organic EL devices using the above-described materials may not have sufficient emission efficiency, and an organic EL device having higher emission efficiency is desirable.

Embodiments provide a compound for an organic EL device having high efficiency and an organic EL device including the same.

Particularly, embodiments provide a compound for an organic EL device having high efficiency. The compound may be used in an emission layer or a layer of stacked layers disposed between the emission layer and an anode, and an organic EL device including the same.

The compound for an organic EL device according to an embodiment may be an amine derivative containing a silyl group including at least one electron withdrawing group. The emission efficiency of the organic EL device may be improved by controlling the highest occupied molecular orbital (HOMO) level.

In some embodiments, the compound for an organic EL device may be an amine derivative combined with a silyl group containing an electron withdrawing group via an arylene group having 6 to 18 ring carbon atoms. The emission efficiency of the organic EL device may be improved.

In some embodiments, a hole transport material may include the compound for an organic EL device described above. A hole transport material according to an embodiment may include an amine derivative containing at least one electron withdrawing group in a silyl group. The emission efficiency of the organic EL device may be improved by controlling the HOMO level of the amine derivative.

In still other embodiments, organic EL devices may include the material for an organic EL device described above in an emission layer.

In the organic EL device according to an embodiment, the emission layer may be formed using an amine derivative containing at least one electron withdrawing group in a silyl group. The HOMO level of the emission layer may be increased, and emission efficiency may be improved.

In even other embodiments, organic EL devices may include the material for an organic EL device described above in a layer of stacked layers disposed between an emission layer and an anode.

In the organic EL device according to an embodiment, the layer of stacked layers disposed between the emission layer and the anode may include an amine derivative containing at least one electron withdrawing group in a silyl group. The HOMO level may be increased, and emission efficiency may be improved.

According to embodiments, a material for an organic EL device having high efficiency and an organic EL device using the same are provided. A material for an organic EL device having high efficiency used in an emission layer or a layer of stacked layers disposed between the emission layer and an anode, and an organic EL device using the same are provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A compound for an organic electroluminescence (EL) device represented by the following Formula (1): 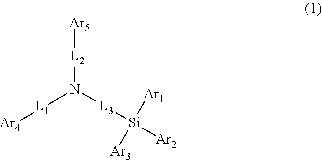
where Ar₁, Ar₂ and Ar₃ are independently a substituted or unsubstituted aryl group, a substituted or unsubstituted heteroaryl group, or a substituted or unsubstituted alkyl group,
at least one of Ar₁, Ar₂ and Ar₃ includes an electron withdrawing group,
Ar₄ and Ar₅ are independently a substituted or unsubstituted aryl group having 6 to 30 ring carbon atoms, a substituted or unsubstituted heteroaryl group having 1 to 30 ring carbon atoms, or a substituted or unsubstituted alkyl group having 1 to 15 carbon atoms, and
L₁, L₂ and L₃ are a single bond or a divalent conjugated connecting group.

2. The compound for an organic EL device as claimed in claim 1, wherein L₃ is an arylene group having 6 to 18 ring carbon atoms.

3. A hole transport material comprising the compound for an organic electroluminescence (EL) device as claimed in claim 1.

4. A hole transport material comprising the compound for an organic electroluminescence (EL) device as claimed in claim 2.

5. An organic electroluminescence (EL) device, comprising the compound for an organic EL device as claimed in claim 1 in an emission layer.

6. An organic electroluminescence (EL) device, comprising the compound for an organic EL device as claimed in claim 2 in an emission layer.

7. An organic electroluminescence (EL) device, comprising the compound for an organic EL device as claimed in claim 1 in a layer of stacked layers between an emission layer and an anode.

8. An organic electroluminescence (EL) device, comprising the compound for an organic EL device as claimed in claim 2 in a layer of stacked layers between an emission layer and an anode.

9. An organic electroluminescence (EL) device, comprising an anode, a hole injection layer, a hole transport layer, an emission layer, an electron transport layer, an electron injection layer, and a cathode stacked in order,
one layer of the hole injection layer, the hole transport layer and the emission layer includes a compound for an organic EL device represented by the following Formula (1): 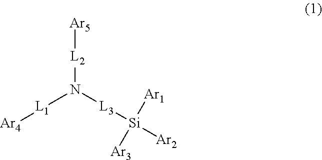
where Ar₁, Ar₂ and Ar₃ are independently a substituted or unsubstituted aryl group, a substituted or unsubstituted heteroaryl group, or a substituted or unsubstituted alkyl group,
at least one of Ar₁, Ar₂ and Ar₃ includes an electron withdrawing group,
Ar₄ and Ar₅ are independently a substituted or unsubstituted aryl group having 6 to 30 ring carbon, a substituted or unsubstituted heteroaryl group having 1 to 30 ring carbon, or a substituted or unsubstituted alkyl group having 1 to 15 carbon atoms, and
L₁, L₂ and L₃ are a single bond or a divalent conjugated connecting group.

10. The compound for an organic EL device as claimed in claim 1, the compound being at least one of the compounds illustrated in the following structures 1 to 12: 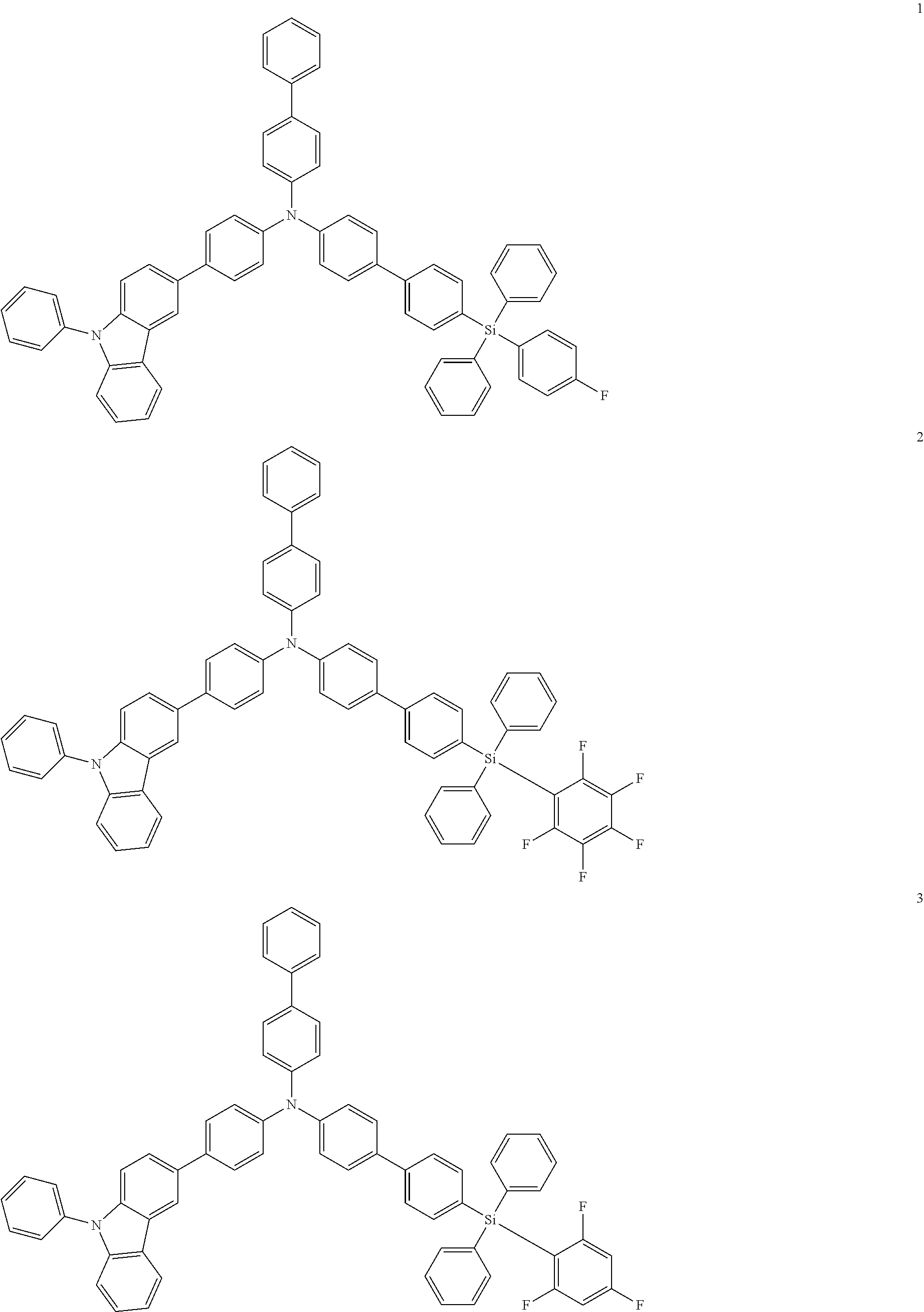 [SMILES: Fc1ccc([Si](c2ccccc2)(c2ccccc2)c2ccc(-c3ccc(N(c4ccc(-c5ccccc5)cc4)c4ccc(-c5ccc6c(c5)c5ccccc5n6-c5ccccc5)cc4)cc3)cc2)cc1 ; Fc1c(F)c(F)c([Si](c2ccccc2)(c2ccccc2)c2ccc(-c3ccc(N(c4ccc(-c5ccccc5)cc4)c4ccc(-c5ccc6c(c5)c5ccccc5n6-c5ccccc5)cc4)cc3)cc2)c(F)c1F ; Fc1cc(F)c([Si](c2ccccc2)(c2ccccc2)c2ccc(-c3ccc(N(c4ccc(-c5ccccc5)cc4)c4ccc(-c5ccc6c(c5)c5ccccc5n6-c5ccccc5)cc4)cc3)cc2)c(F)c1] 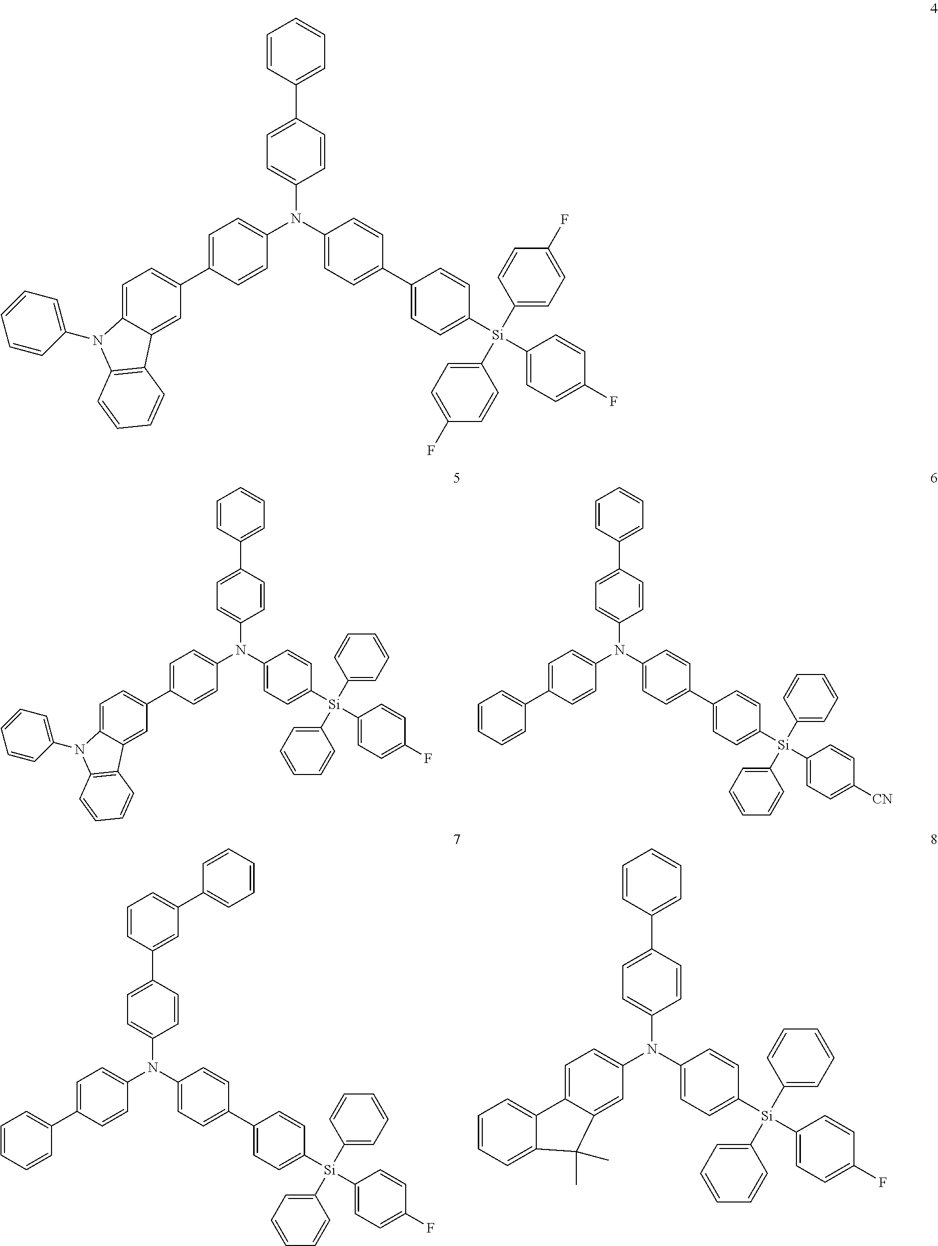 [chemical structure]
